(19) United States
(12) Patent Application Publication
(10) Pub. No.: US 2005/0101070 A1
(43) Pub. Date: May 12, 2005

(54) Method of manufacturing semiconductor device

(75) Inventors: Mikio Tsujiuchi, Tokyo (JP); Toshiaki Iwamatsu, Tokyo (JP)

Correspondence Address: MCDERMOTT, WILL & EMERY, 600 13th Street, N.W., WASHINGTON, DC, 20005-3096, US

(73) Assignee: RENESAS TECHNOLOGY CORP.

(21) Appl. No.: 10/978,796

(22) Filed: Nov. 2, 2004

(30) Foreign Application Priority Data
Nov. 6, 2003 (JP) JP2003-376639

(51) Int. Cl. H01L 21/00; H01L 21/336

(52) U.S. Cl. 438/151; 438/424

(57) ABSTRACT

An SOI substrate is formed of a silicon oxide substrate and a silicon film. A surface of the silicon film is oxidized and a silicon oxide film is thereby formed. A polycrystalline silicon and a silicon nitride film are formed on the silicon oxide film in this order. Then, a trench is formed in a region. The trench is filled with an insulating material, e.g., a silicon oxide film.

### BACKGROUND OF THE INVENTION

1. Field of the Invention

The present invention relates to a method of manufacturing a semiconductor device, and the present invention can be applied to a transistor, an integrated circuit and a memory, for example.

2. Description of the Background Art

As one of techniques to manufacture a semiconductor device, conventionally, a device having a MOS (Metal Oxide Semiconductor) structure or the like is formed on an SOI (Silicon on Insulator) substrate. Further, for device isolation, pn junction isolation, oxide isolation (e.g., LOCOS (Local Oxidation of Silicon) method) and the like are used.

Patent Document 1, Japanese Patent Application Laid Open Gazette No. 10-209446 (1998), discloses a technique of lowering concentration of contaminants in a silicon substrate to prevent diffusion of the contaminants in an oxide film which is formed later. Patent Document 2, National Publication of Translation No. 11-513538 (1999), discloses a technique of forming a trench isolation region for device isolation. Non-Patent Document 1, “Advanced Shallow Trench Isolation to Suppress the Inverse Narrow Channel Effects for 0.24 μm Pitch Isolation and Beyond” by K. Horita et al. (seven people), 2000 Symposium on VLSI Technology Digest of Technical Papers, 2000, pp. 178-179, shows a technique of using a multilayer structure consisting of a silicon nitride film, a polycrystalline silicon and a silicon oxide film as a mask of CMP discussed later. Non-Patent Document 2, “Science of Silicon” supervised by Tadahiro Ohmi and others, published by REALIZE Inc., p. 1015, shows relations between respective diffusion coefficients of contaminating metals and temperatures.

In formation of a device on an SOI substrate, metal contaminants are left between layers and in formation of a trench for device isolation, the metal contaminant are adhered to a trench bottom. The metal contaminants cause deterioration in performance and reliability of a semiconductor device.

Until now, some methods of removing metal contaminants have been suggested. Specifically, before formation of a gate insulating film on a silicon surface, a sacrificial oxide film is formed at a position where the gate insulating film is formed. Then, the metal contaminants are diffused and flocculated in an interface between the silicon and the sacrificial oxide film and removed when the sacrificial oxide film is removed.

This method, however, may arise the following possible problem. Specifically, the flocculated metal contaminants leave a dent on the silicon surface and if the gate insulating film is formed on the silicon surface with the dent, there arises a stress in the dent and this gives a crack in the insulating film, causing a dielectric breakdown.

### SUMMARY OF THE INVENTION

It is an object of the present invention to prevent deterioration in performance and reliability of a semiconductor device.

The present invention is intended for a method of manufacturing a semiconductor device. In a first aspect of the present invention, the method includes the following steps (a) to (e). The step (a) is to layer a silicon oxide film, a polycrystalline silicon and a silicon nitride film on a silicon film formed on a silicon oxide substrate in this order. The step (b) is to etch the silicon nitride film, the polycrystalline silicon, the silicon oxide film and the silicon film in a predetermined region to form a trench having a bottom surface in the silicon film. The step (c) is to form an insulating film on a surface of the silicon film which is exposed at the trench. The step (d) is to remove the insulating film. The step (e) is to fill the trench with an insulating material.

By executing the step (c), metal contaminants are diffused and flocculated in an interface between the silicon film and the insulating film and removed when the insulating film is removed. Therefore, it is possible to prevent deterioration in performance and reliability of the semiconductor device.

In a second aspect of the present invention, the method includes the following steps (a) to (d). The step (a) is to layer a silicon oxide film, a polycrystalline silicon and a silicon nitride film on a silicon film formed on a silicon oxide substrate in this order. The step (b) is to etch the silicon nitride film, the polycrystalline silicon, the silicon oxide film and the silicon film in a predetermined region to form a trench having a bottom surface in the silicon film. The step (c) is to perform wet etching to remove the thickness ranging from 1 to 20 nm of a surface of the silicon film which is exposed at the trench. The step (d) is to fill the trench with an insulating material.

By executing the step (c), metal contaminants which are adhered to the surface of the silicon film are removed. Therefore, it is possible to prevent deterioration in performance and reliability of the semiconductor device.

In a third aspect of the present invention, the method includes the following steps (a) to (e). The step (a) is to layer a silicon oxide film, a polycrystalline silicon and a silicon nitride film on a silicon film formed on a silicon oxide substrate in this order. The step (b) is to etch the silicon nitride film, the polycrystalline silicon, the silicon oxide film and the silicon film in a predetermined region to form a trench having a bottom surface in the silicon film. The step (c) is to form an oxide film on a surface of the silicon film which is exposed at the trench. The step (d) is to fill the trench with an insulating material. The step (e) is to perform annealing at a temperature of 600° C. or lower for one hour or more.

By executing the step (e), metal contaminants are diffused and flocculated in an interface between the silicon film and the oxide film. Therefore, it is possible to prevent deterioration in performance and reliability of the semiconductor device.

These and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a conceptual plan view showing a semiconductor device;

FIGS. 2 to 10 are cross sections showing a semiconductor device in manufacturing steps discussed in a first preferred embodiment;

FIG. 11 is a cross section showing a manufactured semiconductor device which is discussed in the first preferred embodiment;

FIGS. 12 to 14 are cross sections showing a semiconductor device in manufacturing steps discussed in a second preferred embodiment;

FIGS. 15 to 17 are cross sections showing a semiconductor device in manufacturing steps discussed in a third preferred embodiment;

FIGS. 18 to 22 are cross sections showing a semiconductor device in manufacturing steps discussed in a fourth preferred embodiment;

FIG. 23 is a cross section showing a semiconductor device in a manufacturing step where an insulating material and a silicon film have curved shapes;

FIG. 24 is a graph showing a relation between a temperature of Fe (iron) and a diffusion length thereof, which is discussed in the first preferred embodiment;

FIG. 25 is a graph showing a relation between a temperature of Ni (nickel) and a diffusion length thereof, which is discussed in the first preferred embodiment;

FIG. 26 is a graph showing a relation between a temperature of Co (cobalt) and a diffusion length thereof, which is discussed in the first preferred embodiment;

FIG. 27 is a graph showing a relation between a temperature of Ti (titanium) and a diffusion length thereof, which is discussed in the first preferred embodiment;

FIG. 28 is a graph showing a relation between a temperature of Al (aluminum) and a diffusion length thereof, which is discussed in the first preferred embodiment; and

FIG. 29 is a graph showing a relation between a temperature of Cr (chromium) and a diffusion length thereof, which is discussed in the first preferred embodiment.

### DESCRIPTION OF THE PREFERRED EMBODIMENTS

The First Preferred Embodiment

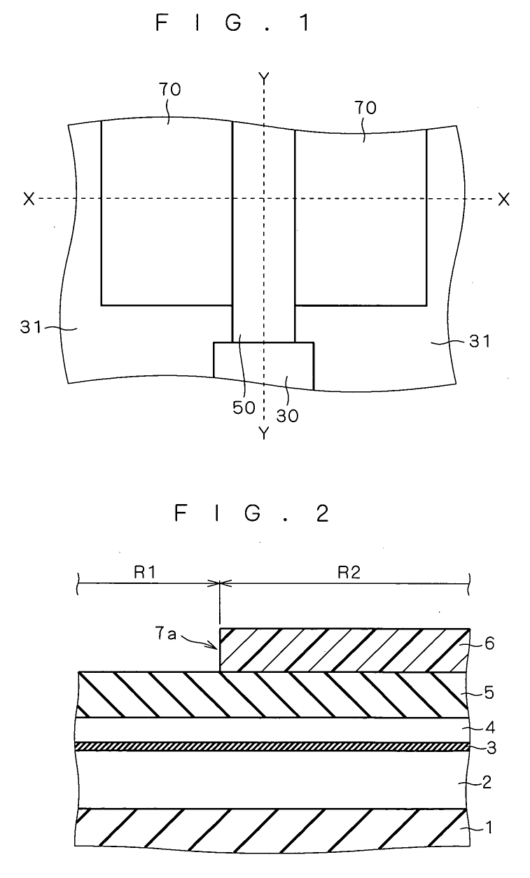

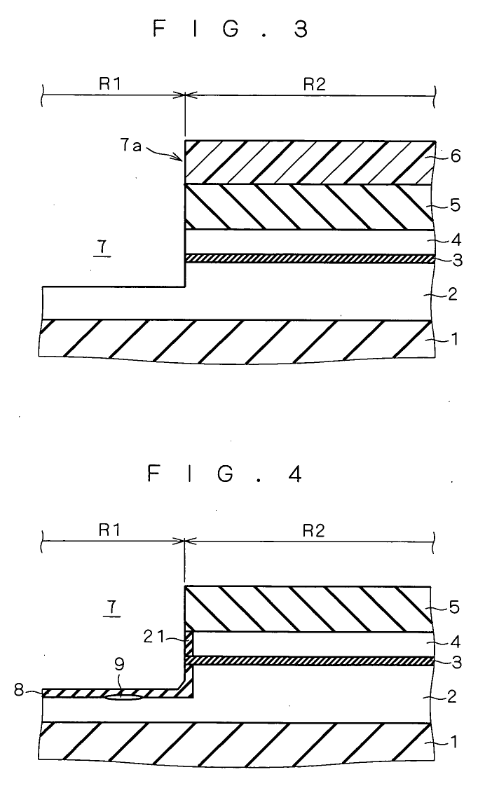

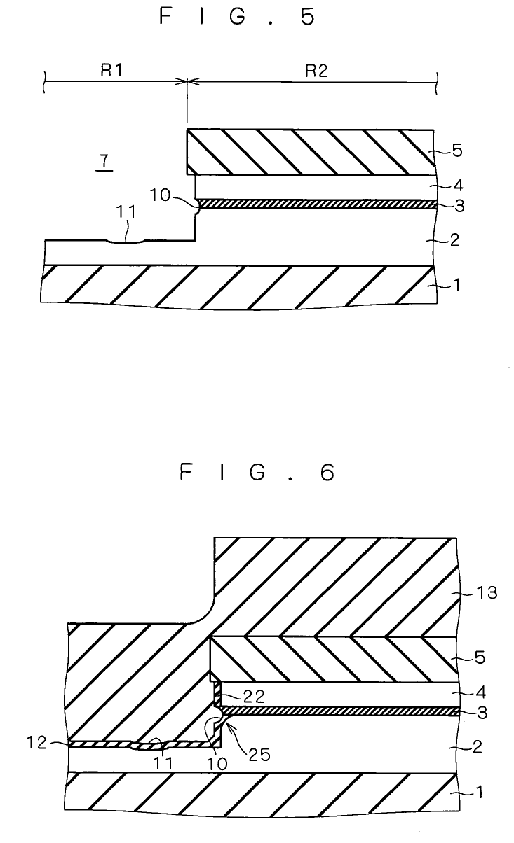

In the first preferred embodiment, the inside of a trench is oxidized at a low temperature. FIG. 1 is a plan view showing a semiconductor device manufactured by a method discussed in the first preferred embodiment. FIGS. 10 and 11 are conceptual cross sections taken along the lines Y-Y and X-X of FIG. 1, respectively. FIGS. 2 to 10 are cross sections along the line Y-Y of FIG. 1, showing a process of forming a MOS device on an SOI substrate step by step. The MOS device discussed in this specification, however, do not necessarily use a metal but may use a conductive semiconductor as a material of a gate electrode.

In the first step, an SOI substrate is formed of a silicon oxide substrate 1 and a silicon film 2. A silicon oxide film 3 is formed by oxidation on a surface of the silicon film 2 on its side opposite to the silicon oxide substrate 1. On the silicon oxide film 3, a polycrystalline silicon 4 and a silicon nitride film 5 are layered in this order. A region R1 is provided to form a structure for device isolation and a region R2 is provided to form devices. On the silicon nitride film 5, a resist resin 6 is layered, which is opened on the region R1 and covers the region R2. An end surface 7a of the resist resin 6 is positioned at a boundary of the regions R1 and R2 (FIG. 2).

In each of stages where the silicon oxide film 3, the polycrystalline silicon 4 and the silicon nitride film 5 are formed, there is a possibility that metal contaminants should be adhered thereto. Among the metal contaminants are iron (Fe), nickel (Ni), cobalt (Co), titanium (Ti), aluminum (Al), chromium (Cr) and the like.

In the second step, in accordance with a pattern formed by the end surface 7a of the resist resin 6, the silicon nitride film 5, the polycrystalline silicon 4, the silicon oxide film 3 and the silicon film 2 are etched to form a trench 7 in the region R1. As to the trench 7 which is hollow and opening to a surface of the resist resin 6, its bottom surface is positioned in the silicon film 2 (FIG. 3). Also in formation of the trench 7, there is a possibility that metal contaminants should be adhered onto the bottom surface of the trench 7.

In the third step, the resist resin 6 is removed and an insulating film is formed on a surface of the silicon film 2 which is exposed at the trench 7 at a temperature of 600° C. or lower. As a method of forming the insulating film, radical oxidation, high-density plasma oxidation or the like is adopted. In performing the high-density plasma oxidation, for example, with a substrate temperature that is set in the range from 200° to 600° C., excitation energy is given to the substrate with plasma. This causes an oxidation reaction on the surface of the silicon film 2 which is exposed at the trench 7 and a silicon oxide film 8 is thereby formed as an insulating film. With this reaction, a portion of the polycrystalline silicon 4 which is exposed at a side surface of the trench 7 is also oxidized and a silicon oxide film 21 is thereby formed. The metal contaminants adhered on the bottom surface of the trench 7 are flocculated in an interface between the silicon oxide film 8 and the silicon film 2 or inside the silicon oxide film 8 to become a metal silicide 9.

The thickness of the silicon oxide film 8 to be formed may depend on the depth at which the metal contaminants adhered on the bottom surface of the trench 7 penetrate the silicon film 2 and where the metal contaminants should be flocculated. The metal contaminants may be flocculated in the interface between the silicon oxide film 8 and the silicon film 2 or inside the silicon oxide film 8. Assuming that the penetration depth of the metal contaminants is 10 nm at the maximum, for example, the thickness of the silicon oxide film 8 should be about 1 to 10 nm if the metal contaminants are flocculated in the interface between the silicon oxide film 8 and the silicon film 2 and it should be about 1 to 30 nm if the metal contaminants are flocculated inside the silicon oxide film 8. Such a manner of deciding the film thickness can be applied to a case discussed later where a silicon nitride film is formed as the insulating film on the surface of the silicon film 2.

In the fourth step, the silicon oxide film 8 formed in the third step is removed by using an HF (hydrofluoric acid) solution. With this removal, the metal silicide 9 is also removed and a dent 11 is formed on the silicon film 2 in the trench 7. At this time, a portion of the silicon oxide film 3 formed in the first step which is exposed at the side surface of the trench 7 is also eroded by the HF solution and the eroded portion becomes a dent 10. The silicon oxide film 21 formed in the third step is also removed by the HF solution (FIG. 5).

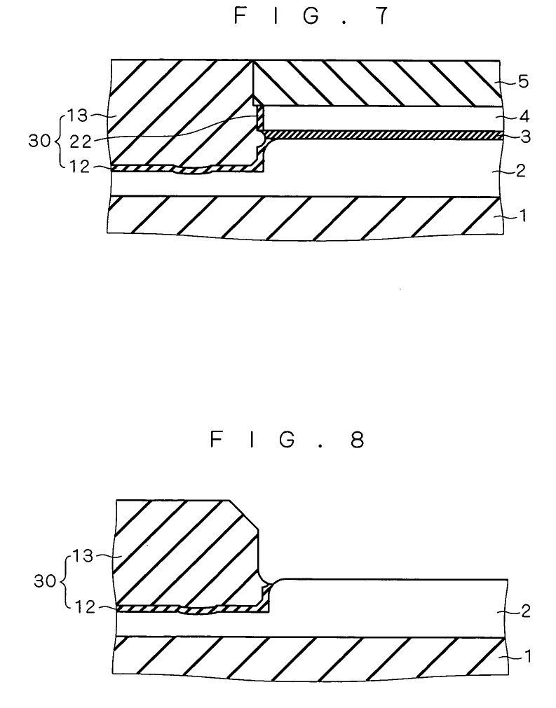

In the fifth step, by performing oxidation again, a silicon oxide film 12 is formed on the surface of the silicon film 2 which is exposed at the trench 7. With this oxidation, a portion of the polycrystalline silicon 4 which is exposed at the side surface of the trench 7 is also oxidized and a silicon oxide film 22 is thereby formed. At this oxidation the temperature does not have the necessity to be 600° C. or lower, unlike the oxidation for forming the silicon oxide film 8. After that, an insulating material to fill the trench 7 and cover a surface of the silicon nitride film 5, e.g., a silicon oxide film 13, is deposited. The silicon oxide film 13 deposited on the trench 7 and that on the silicon nitride film 5 are continuous (FIG. 6).

In formation of the silicon oxide film 12, there is a possibility that a stress arises in the dent 10, which causes a crack. Since the trench 7 filled with the silicon oxide film 13, however, functions as a structure for device isolation, presence of the crack is not a problem to this function.

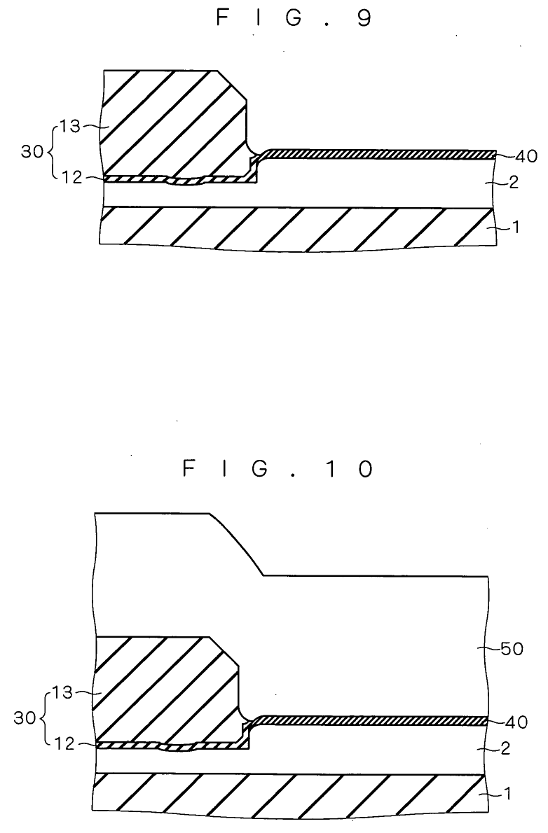

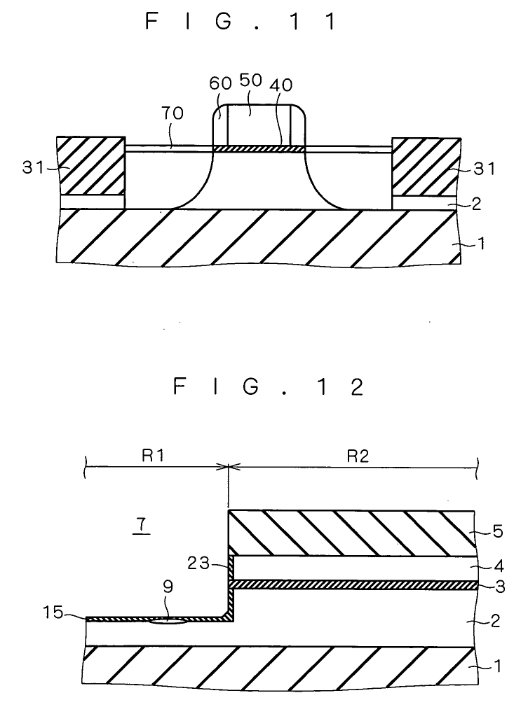

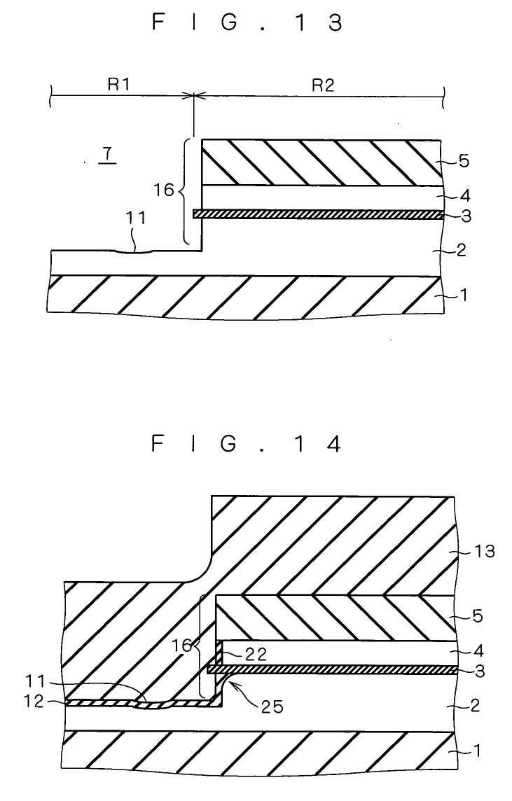

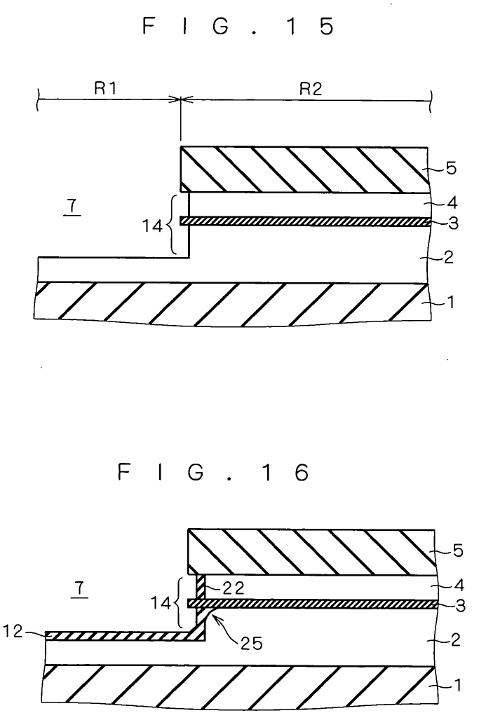

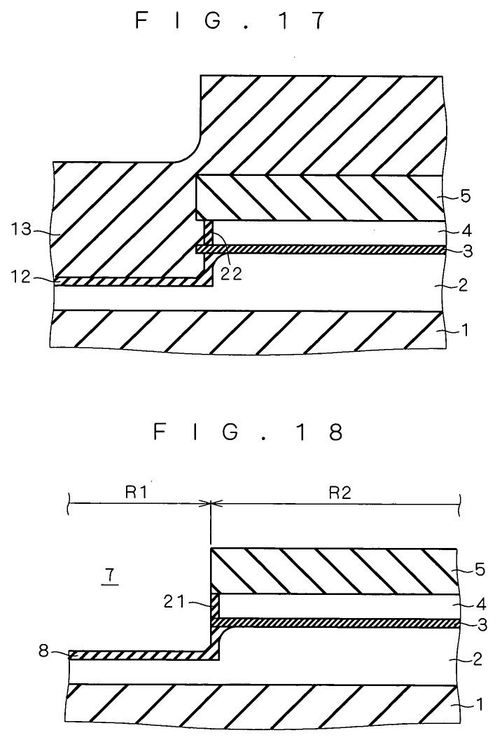

In the sixth step, the silicon oxide film 13 formed in the fifth step is polished and planarized by CMP (Chemical and Mechanical Polishing) and the whole surface of the silicon nitride film 5 is exposed (FIG. 7). At this time, the silicon oxide films 12 and 13 left inside the trench 7 serve as an oxide film for device isolation, i.e., an isolation oxide film 30.

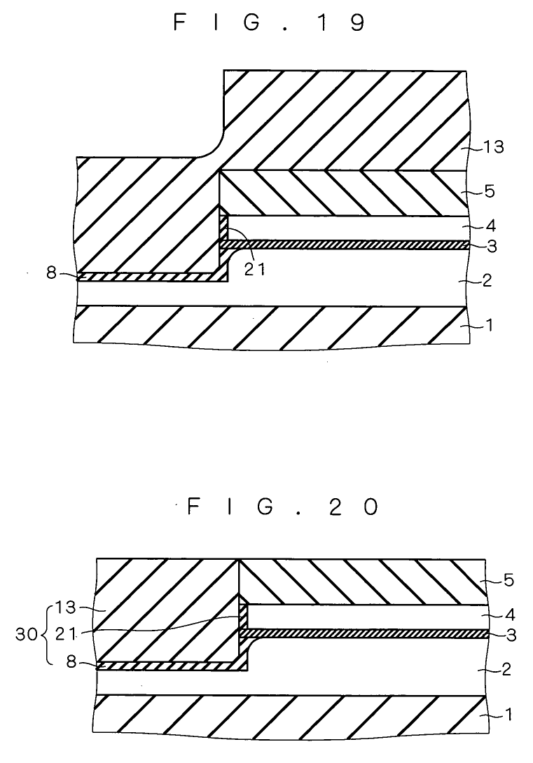

In the seventh step, the silicon nitride film 5, the polycrystalline silicon 4, the silicon oxide film 3 and the silicon oxide film 22 are removed (FIG. 8). The surface of the silicon film 2 which is exposed by this removal of these films is oxidized, to thereby form a silicon oxide film 40 (FIG. 9). Then, on surfaces of the silicon oxide films 13 and 40, a polycrystalline silicon 50 is deposited (FIG. 10).

In the eighth step, after the seventh step, through pattern etching of the polycrystalline silicon 50, formation of an insulating film and pattern etching of the insulating film, an insulating film 60 is formed on a side surface of the polycrystalline silicon 50. Then, through implantation of impurity ions and formation of a metal silicide film 70, a semiconductor device is completed (FIG. 11).

The metal contaminants are likely to be diffused and flocculated at a portion of the semiconductor device which has a relative large stress. Since it is thought that the stress on the trench 7 is larger than that on other portions, the metal contaminants adhered on the bottom surface of the trench 7 become likely to be left there in oxidation.

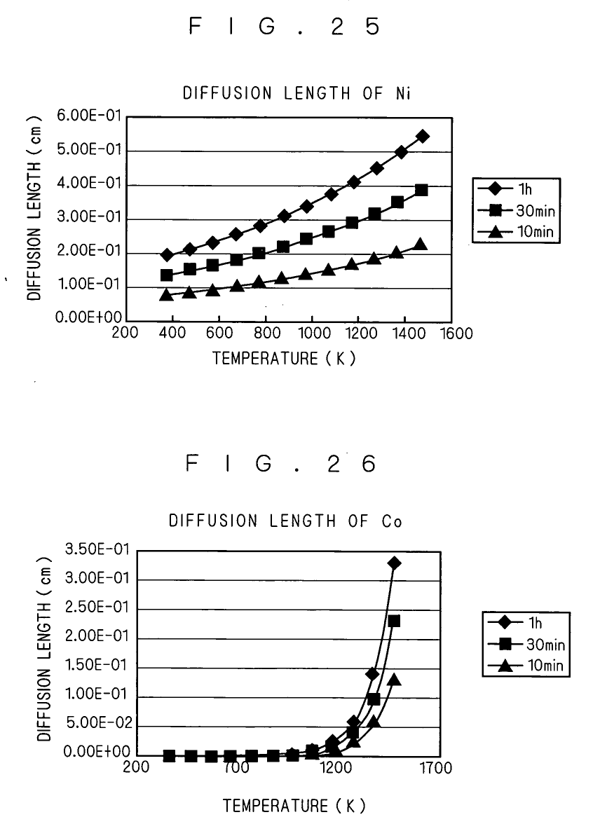

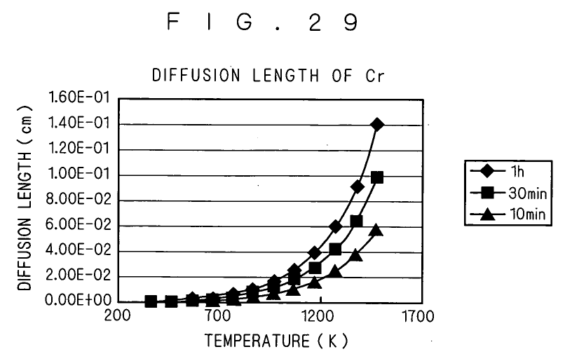

On the other hand, diffusion of the metal contaminants depends on a temperature. FIGS. 24 to 29 show relations between the temperatures of metal contaminants and their diffusion lengths, for types of metal contaminants. The diffusion length of a metal contaminant is obtained by √(D×t), where D represents a diffusion coefficient (cm²/sec) and t represents a diffusion time (sec). The diffusion coefficient D can be obtained for each metal contaminant from the relations between diffusion coefficients D and temperatures shown in FIG. 1 in Non-Patent Document 2.

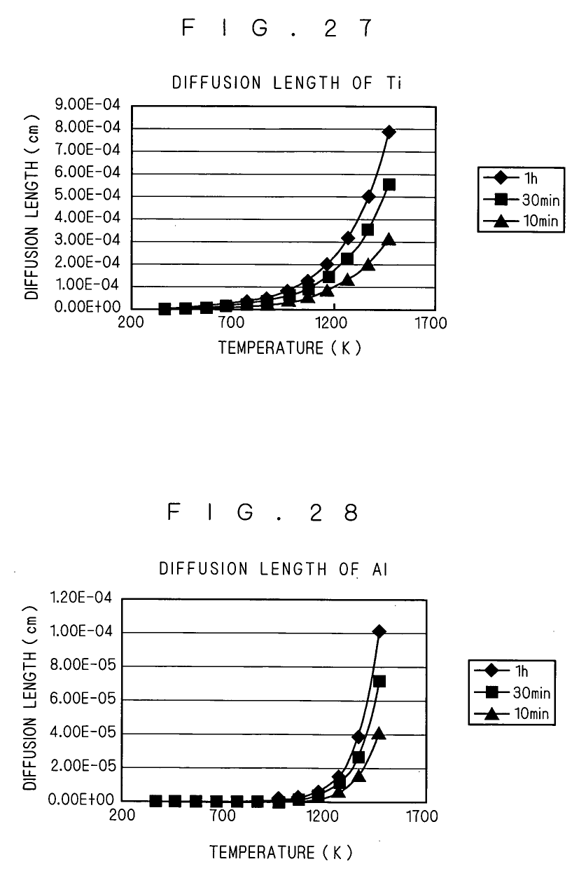

Since a temperature at which the silicon oxide film 8 is formed on the surface of the silicon film 2 is 600° C. or lower (the unit of temperature indicated by the horizontal axis of the graph is Kelvin (K) and 600° C. corresponds to 873 K), it can be seen from FIGS. 24 to 29 that the diffusion lengths become smaller at this temperature. For this reason, the metal contaminant on the bottom surface of the trench 7 is hard to diffuse from the region R1 to the region R2 and likely to be flocculated in the interface between the silicon oxide film 8 and the silicon film 2 or inside the silicon oxide film 8. As shown in FIGS. 26 to 29, the diffusion lengths of Co, Ti, Al and Cr are very small at a temperature of 600° C. or lower, and the first preferred embodiment is especially effective for these metal contaminants. Therefore, with the method of the first preferred embodiment, it is possible to remove the metal contaminants incorporated in the semiconductor device during manufacturing process and prevent deterioration in performance and reliability of the semiconductor device.

Formation of the silicon oxide film 8 is effective not only for the removal of the metal contaminants adhered to the bottom surface of the trench 7 but also for the removal of the metal contaminants present in the respective interfaces of the silicon film 2, the silicon oxide film 3, the polycrystalline silicon 4 and the silicon nitride film 5 formed in the first step (the interfaces in the region R2). In other words, by formation of the silicon oxide film 8, the metal contaminants present in the interfaces in the region R2 are diffused and flocculated in the interface between the silicon film 2 and the silicon oxide film 8 or inside the silicon oxide film 8 and thereby become the metal silicide 9. Therefore, formation of the silicon oxide film 8 is effective especially for Fe, Ni or the like which have large diffusion lengths also at a temperature of 600° C. or lower shown in FIGS. 24 and 25.

Also in this case, like in the above-discussed case, the metal silicide 9 is removed together with the silicon oxide film 8 by using the HF solution. Therefore, by formation of the silicon oxide film 8, it is possible to remove the metal contaminants incorporated in the semiconductor device during manufacturing process and prevent deterioration in performance and reliability of the semiconductor device.

In the third step, plasma nitriding may be performed on the surface of the silicon film 2 exposed at the trench 7. In this case, with a substrate temperature that is set in the range from 200° to 600° C., excitation energy is given to the substrate with plasma. This causes a nitriding reaction on the surfaces of the silicon film 2 and the polycrystalline silicon 4 which are exposed at the trench 7, and a silicon nitride film is formed as an insulating film. The metal contaminants are diffused and flocculated in an interface between the silicon nitride film and the silicon film 2 or inside the silicon nitride film, to become the metal silicide 9. After that, in the fourth step, by using a phosphoric acid solution instead of the HF solution, the metal silicide 9 is removed together with the silicon nitride film.

In the third step, oxidation may be performed on the surface of the silicon film 2 exposed at the trench 7 by using an ozone solution. In this case, a substrate temperature is set in the range from 20° to 120° C. This causes an oxidation reaction on the surfaces of the silicon film 2 and the polycrystalline silicon 4 which are exposed at the trench 7, and the silicon oxide film 8 is formed as an insulating film. The metal contaminants are diffused and flocculated in the interface between the silicon oxide film 8 and the silicon film 2 or inside the silicon oxide film 8, to become the metal silicide 9. After that, in the fourth step, the metal silicide 9 is removed together with the silicon oxide film 8 by using the HF solution.

By performing nitriding with plasma or oxidation with the ozone solution on the surface of the silicon film 2, it is also possible to remove the metal contaminants incorporated in the semiconductor device during manufacturing process, like in the above-discussed case of performing oxidation with, e.g., plasma. Therefore, it is possible to prevent deterioration in performance and reliability of the semiconductor device.

The Second Preferred Embodiment

In the second preferred embodiment, annealing is performed under a nitrogen atmosphere. FIGS. 12 to 14 are conceptual cross sections along the line Y-Y of FIG. 1, showing a process of forming a MOS device on an SOI substrate step by step.

In the first step, like in the first and second steps in the first preferred embodiment, various films are formed on the SOI substrate and after that, the trench 7 is formed (FIG. 3). In this case, there are possibilities that the metal contaminants should be adhered to the films in each of the stages where the silicon film 2, the silicon oxide film 3, the polycrystalline silicon 4 and the silicon nitride film 5 are formed and that the metal contaminants should be adhered onto the bottom surface of the trench 7.

In the second step, the resist resin 6 is removed and nitriding is performed. In this nitriding, the surface of the silicon film 2 is annealed under a nitrogen atmosphere at a temperature in the range from 800° to 1200° C. for 30 seconds to 4 hours. With this nitriding, a silicon nitride film 15 is formed as an insulating film on the surface of the silicon film 2 exposed at the trench 7. With this, a portion of the polycrystalline silicon 4 which is exposed at the side surface of the trench 7 is nitrided and a silicon nitride film 23 is thereby formed. The metal contaminants present in the respective interfaces of the silicon film 2, the silicon oxide film 3, the polycrystalline silicon 4 and the silicon nitride film 5 are diffused and flocculated in the interface between the silicon film 2 and the silicon nitride film 15 or inside the silicon nitride film 15 and thereby become the metal silicide 9 (FIG. 12).

Like in the first preferred embodiment, the thickness of the silicon nitride film 15 to be formed may depend on the depth at which the metal contaminants adhered on the bottom surface of the trench 7 penetrate the silicon film 2 and where the metal contaminants should be flocculated.

In the third step, the silicon nitride film 15 formed in the second step is removed by using a phosphoric acid solution at a temperature in the range from 20° to 180° C. With this removal, the metal silicide 9 is also removed and the dent 11 is formed on the silicon film 2 in the trench 7. At that time, a portion of the silicon nitride film 5 formed in the first step, which is exposed at the side surface of the trench 7, is also eroded by the phosphoric acid solution. Further, the silicon nitride film 23 is removed by the phosphoric acid solution. At this time, since the silicon oxide film 3 does not react with the phosphoric acid solution, the side surface of the trench 7 has a shape 16 with protrusion of the silicon oxide film 3 (FIG. 13).

For removal of the silicon nitride film 15, the HF solution at a temperature in the range from 20° to 100° C. may be used. Also in this case, the metal silicide 9 is removed.

In the fourth step, with oxidation, the silicon oxide film 12 is formed on the surface of the silicon film 2 exposed at the trench 7. With this oxidation, a portion of the polycrystalline silicon 4 which is exposed at the side surface of the trench 7 is also oxidized, to thereby form the silicon oxide film 22. After that, an insulating material to fill the trench 7 and cover the surface of the silicon nitride film 5, e.g., the silicon oxide film 13, is deposited. The silicon oxide film 13 deposited on the trench 7 and that on the silicon nitride film 5 are continuous (FIG. 14).

In formation of the silicon oxide film 12, there is a possibility that a stress arises in the dent 10, which causes a crack. Since the trench 7 filled with the silicon oxide film 13, however, functions as a structure for device isolation, presence of the crack is not a problem to this function.

In the fifth step, like in the sixth to eighth steps discussed in the first preferred embodiment, a semiconductor device is completed.

It is thought that the stress on the trench 7 is larger than that on other portions of the semiconductor device. For this reason, the metal contaminants diffused by annealing to the interface between the silicon film 2 and the silicon nitride film 15 become likely to be left and flocculated there. Further, it is thought that the annealing time that is set in the range from 30 seconds to 4 hours is enough for the metal contaminants to reach the interface between the silicon film 2 and the silicon nitride film 15.

For example, in a case where the length where the metal contaminants such as Fe, Ni, Co and Cr should be diffused is 0.1 mm, if the temperature is set 1200° C., a diffusion time ranging from 1.22 to 18.3 seconds is needed and if the temperature is set 800° C., a diffusion time ranging from 2.60 seconds to 53.6 minutes is needed. In a case where the length where the metal contaminants should be diffused is 1 mm, if the temperature is set 1200° C., a diffusion time ranging from 2.03 to 30.4 minutes is needed and if the temperature is set 800° C., a diffusion time ranging from 4.34 minutes to 89.4 hours is needed. Thus, the annealing time depends on the type of metal contaminant, a temperature and a diffusion length.

Considering the above discussion, annealing of the surface of the silicon film 2 under a nitrogen atmosphere at a temperature in the range from 800° to 1200° C. for 30 seconds to 4 hours makes the metal contaminants in the region R2 likely to be diffused to the region R1 and flocculated in the interface between the silicon film 2 and the silicon nitride film 15. Therefore, it is possible to remove the metal contaminants incorporated in the semiconductor device during manufacturing process and prevent deterioration in performance and reliability of the semiconductor device.

Annealing under a nitrogen atmosphere at a temperature in the range from 800° to 1200° C. among the characteristic features of the second preferred embodiment is effective not only for the removal of the metal contaminants present in the respective interfaces of the silicon film 2, the silicon oxide film 3, the polycrystalline silicon 4 and the silicon nitride film 5 but also for the removal of the metal contaminants adhered to the bottom surface of the trench 7.

In the second step, annealing of the surface of the silicon film 2 exposed at the trench 7 may be performed under an argon/oxygen atmosphere at a temperature in the range from 800° to 1200° C. In this case, the surface of the silicon film 2 is oxidized, to thereby a silicon oxide film as an insulating film, and microscopic uneven spots are formed in the interface between the silicon film 2 and the silicon oxide film. The metal contaminants which become likely to be left there due to the presence of the uneven spots are flocculated in the interface between the silicon oxide film and the silicon film 2 or inside the silicon oxide film, to thereby become the metal silicide 9. After that, in the third step, the metal silicide 9 is removed together with the silicon oxide film by the HF solution.

The Third Preferred Embodiment

In the third preferred embodiment, the inside of the trench is etched. FIGS. 15 to 17 are conceptual cross sections along the line Y-Y of FIG. 1, showing a process of forming a MOS device on an SOI substrate step by step.

In the first step, like in the first and second steps in the first preferred embodiment, various films are formed on the SOI substrate and after that, the trench 7 is formed (FIG. 3). In this case, there is a possibility that the metal contaminants should be adhered onto the bottom surface of the trench 7.

In the second step, the resist resin 6 is removed and the surface of the silicon film 2 exposed at the trench 7 is wet-etched by using an ammonia peroxide solution at a temperature in the range from 20° to 150° C. With this wet etching, the metal contaminants adhered to the silicon film 2 are removed. In a case where the penetration depth of the metal contaminants into the silicon film 2 is about 10 nm, for example, it is preferable that the thickness of the silicon film to be removed by wet etching should range from 10 nm to 20 nm. Since the polycrystalline silicon 4 is also etched by the ammonia peroxide solution, respective end surfaces of the polycrystalline silicon 4 and the silicon film 2 exposed at the side surface of the trench 7 are withdrawn and the side surface of the trench 7 has a shape 14 with protrusion of the silicon oxide film 3 (FIG. 15).

In the third step, the surface of the silicon film 2 exposed at the trench 7 is oxidized, to thereby form the silicon oxide film 12. With this oxidation, a portion of the polycrystalline silicon 4 which is exposed at the side surface of the trench 7 is also oxidized, to thereby form the silicon oxide film 22 (FIG. 16). After that, an insulating material to fill the trench 7 and cover the surface of the silicon nitride film 5, e.g., the silicon oxide film 13, is deposited. The silicon oxide film 13 deposited on the trench 7 and that on the silicon nitride film 5 are continuous (FIG. 17).

In the fourth step, like in the sixth to eighth steps discussed in the first preferred embodiment, a semiconductor device is completed.

By using the ammonia peroxide solution, the surface of the silicon film 2 exposed at the trench 7 is etched and the metal contaminants adhered to the bottom surface of the trench 7 is thereby removed. Therefore, by this etching, it is possible to remove the metal contaminants incorporated in the semiconductor device during manufacturing process and prevent deterioration in performance and reliability of the semiconductor device.

In the second step, wet etching of the surface of the silicon film 2 exposed at the trench 7 may be performed by using an ammonia solution at a temperature in the range from 20° to 150° C., a buffered hydrofluoric acid (BHF) solution at a temperature in the range from 20° to 150° C., a potassium hydroxide (KOH) solution at a temperature in the range from 20° to 150° C. or the like. Also this case can produce the same effect as in the case of using the ammonia peroxide solution at a temperature in the range from 20° to 150° C.

In the fifth step of the above-discussed first preferred embodiment, the fourth step of the second preferred embodiment and the third step of the third preferred embodiment, with formation of the silicon oxide film 12 on the surface of the silicon film 2 exposed at the trench 7, an edge portion 25 of the silicon film 2 on the side of the trench 7 has a curved shape (FIGS. 6, 14 and 16). This can reduce an electric field concentration which would possibly occur if the edge portion 25 is angular. Therefore, it is possible to prevent deterioration in performance and reliability of the semiconductor device.

In any one of the above-discussed preferred embodiments, there may be a case where no silicon oxide film 12 is formed but with formation of the silicon oxide film 12, for example, it is possible to avoid the electric field concentration.

The Fourth Preferred Embodiment

In the fourth preferred embodiment, annealing is performed at a low temperature. FIGS. 18 to 22 are conceptual cross sections along the line Y-Y of FIG. 1, showing a process of forming a MOS device on an SOI substrate step by step.

In the first step, like in the first and second steps in the first preferred embodiment, various films are formed on the SOI substrate and after that, the trench 7 is formed (FIG. 3). In this case, there are possibilities that the metal contaminants should be adhered to the films in each of the stages where the silicon film 2, the silicon oxide film 3, the polycrystalline silicon 4 and the silicon nitride film 5 are formed and that the metal contaminants should be adhered onto the bottom surface of the trench 7.

In the second step, the resist resin 6 is removed and oxidation is performed to form the silicon oxide film 8 to be exposed at the trench 7. With this oxidation, a portion of the polycrystalline silicon 4 which is exposed at the side surface of the trench 7 is also oxidized and the silicon oxide film 21 is thereby formed (FIG. 18). After that, an insulating material to fill the trench 7 and cover the surface of the silicon nitride film 5, e.g., the silicon oxide film 13, is deposited. The silicon oxide film 13 deposited on the trench 7 and that on the silicon nitride film 5 are continuous (FIG. 19).

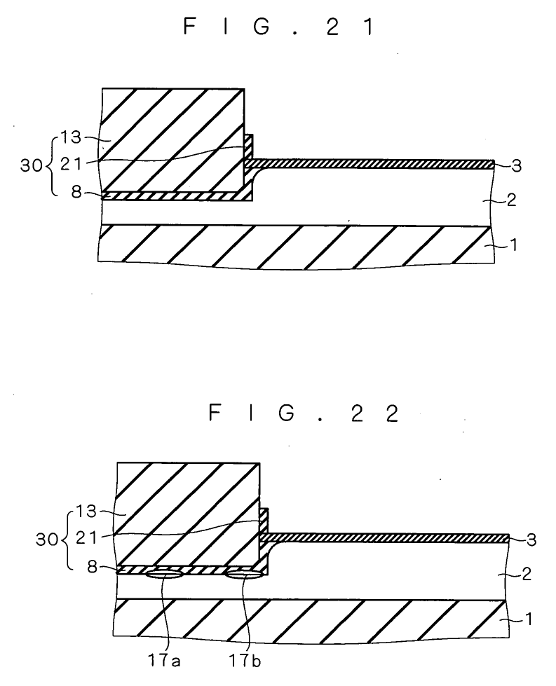

In the third step, the silicon oxide film 13 formed in the second step is polished and planarized by CMP and the whole surface of the silicon nitride film 5 is exposed (FIG. 20). At this time, the silicon oxide films 8, 13 and 21 left inside the trench 7 serve as the isolation oxide film 30. Then, the silicon nitride film 5 and the polycrystalline silicon 4 are removed (FIG. 21).

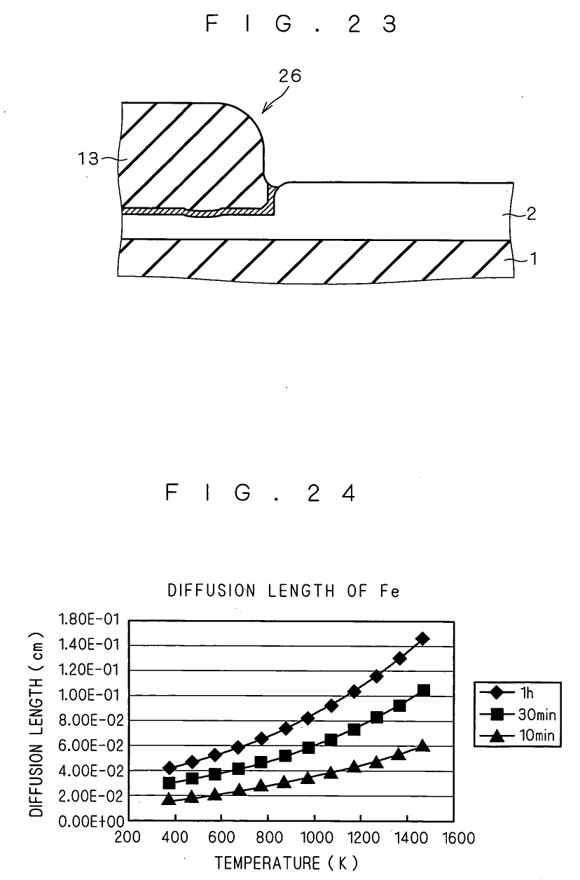

In the fourth step, the whole semiconductor device manufactured in the first to third steps is annealed at a temperature of 600° C. or lower for one hour or more. With this annealing, the metal contaminants incorporated in the first step are flocculated in the interface between the silicon film 2 and the silicon oxide film 8, to become metal silicides 17a and 17b. The metal contaminants adhered in formation of the trench 7 are flocculated to become the metal silicide 17a and the metal contaminants present in the interfaces of the silicon film 2, the silicon oxide film 3, the polycrystalline silicon 4 and the silicon nitride film 5 are diffused and flocculated to become the metal silicide 17b (FIG. 22).

In the fifth step, the polycrystalline silicon 50 is deposited on the surfaces of the silicon oxide films 3, 13 and 21. After that, like in the eight step of the first preferred embodiment, the semiconductor device is completed.

The metal contaminants are likely to be left in the trench 7 which has a stress larger than that in other portions of the semiconductor device. Then, the metal contaminants flocculated in the trench 7 become the metal silicides 17a and 17b. Therefore, almost no metal contaminant is present in a main portion (the region R2) which functions as a device and it is possible to prevent deterioration in performance and reliability of the semiconductor device.

If it is needed to form a well region in the silicon film 2 in the manufacture of the semiconductor device, between the third and fourth steps, i.e., in the state of FIG. 21, the well region may be formed by implanting impurities into the silicon film 2 from the side of the silicon oxide film 3. In this case, by performing annealing in the fourth step, the impurities implanted in the well region are diffused together with the metal contaminants and this possibly causes a case where the impurity concentration in the well region may be out of a set value. For this reason, it is preferable that the impurity concentration in the well region should be controlled again after the annealing.

If it is needed to form the well region in the silicon film 2, the well region may be formed in the silicon film 2 after the fourth step. In this case, it is not necessary to control the impurity concentration in the well region once more and the process is therefore simplified.

In the seventh step of the first preferred embodiment (including a case where this step is adopted in the fourth step of the second preferred embodiment and the fifth step of the third preferred embodiment), by using the annealing method discussed in the fourth step of the fourth preferred embodiment before the removal of the silicon oxide film 3, it is possible to prevent deterioration in performance and reliability of the semiconductor device more efficiently.

In any one of the above-discussed preferred embodiments, the insulating material 13 exposed at the surface on the side of silicon film 2 may have a curved shape after filling the trench 7 with the insulating material 13. FIG. 23, corresponding to, e.g., FIG. 8, shows a state where a portion 26 of the insulating material 13 exposed at the surface on the side of the silicon film 2 has a curved shape.

In the case where the portion 26 of the insulating material 13 has a curved shape, a tilt of the portion 26 of the insulating material 13 with respect to the surface of the silicon film 2 is gentle. Therefore, a process of forming a gate becomes easier.

While the invention has been shown and described in detail, the foregoing description is in all aspects illustrative and not restrictive. It is therefore understood that numerous modifications and variations can be devised without departing from the scope of the invention.

1. A method of manufacturing a semiconductor device, comprising the steps of:
(a) layering a silicon oxide film, a polycrystalline silicon and a silicon nitride film on a silicon film formed on a silicon oxide substrate in this order;
(b) etching said silicon nitride film, said polycrystalline silicon, said silicon oxide film and said silicon film in a predetermined region to form a trench having a bottom surface in said silicon film;
(c) forming an insulating film on a surface of said silicon film which is exposed at said trench;
(d) removing said insulating film; and
(e) filling said trench with an insulating material.

2. The method of manufacturing a semiconductor device according to claim 1, wherein
formation of said insulating film is performed at a temperature of 600° C. or lower in said step (c).

3. The method of manufacturing a semiconductor device according to claim 2, wherein
radical oxidation, plasma oxidation or plasma nitriding is performed on said surface of said silicon film at a temperature in the range from 200° to 600° C. in said step (c).

4. The method of manufacturing a semiconductor device according to claim 2, wherein
said surface of said silicon film is oxidized by using an ozone solution at a temperature in the range from 20° to 120° C. in said step (c).

5. The method of manufacturing a semiconductor device according to claim 1, wherein
annealing is performed at a temperature in the range from 800° to 1200° C. for 30 seconds to 4 hours in said step (c).

6. The method of manufacturing a semiconductor device according to claim 5, wherein
said annealing is performed under a nitrogen atmosphere or an argon/oxygen atmosphere.

7. The method of manufacturing a semiconductor device according to claim 1, further comprising the step of
forming an oxide film on said surface of said silicon film exposed at said trench between said steps (d) and (e).

8. The method of manufacturing a semiconductor device according to claim 1, further comprising the step of
performing annealing at a temperature of 600° C. or lower for one hour or more after said step (e).

9. The method of manufacturing a semiconductor device according to claim 1, further comprising the step of
making said insulating material which is exposed at a surface have a curved shape on a side of said silicon film after said step (e).

10. A method of manufacturing a semiconductor device, comprising the steps of:
(a) layering a silicon oxide film, a polycrystalline silicon and a silicon nitride film on a silicon film formed on a silicon oxide substrate in this order;
(b) etching said silicon nitride film, said polycrystalline silicon, said silicon oxide film and said silicon film in a predetermined region to form a trench having a bottom surface in said silicon film;
(c) performing wet etching to remove the thickness in the range from 1 to 20 nm of a surface of said silicon film which is exposed at said trench; and
(d) filling said trench with an insulating material.

11. The method of manufacturing a semiconductor device according to claim 10, wherein
said wet etching is performed by using one of an ammonia peroxide solution, an ammonia solution, a buffered hydrofluoric acid solution and a potassium hydroxide solution at a temperature in the range from 20° to 150° C. in said step (c).

12. The method of manufacturing a semiconductor device according to claim 10, further comprising the step of
forming an oxide film on said surface of said silicon film exposed at said trench between said steps (c) and (d).

13. The method of manufacturing a semiconductor device according to claim 10, further comprising the step of
performing annealing at a temperature of 600° C. or lower for one hour or more after said step (d).

14. The method of manufacturing a semiconductor device according to claim 10, further comprising the step of
making said insulating material which is exposed at a surface have a curved shape on a side of said silicon film after said step (d).

15. A method of manufacturing a semiconductor device, comprising the steps of:
(a) layering a silicon oxide film, a polycrystalline silicon and a silicon nitride film on a silicon film formed on a silicon oxide substrate in this order;
(b) etching said silicon nitride film, said polycrystalline silicon, said silicon oxide film and said silicon film in a predetermined region to form a trench having a bottom surface in said silicon film;
(c) forming an oxide film on a surface of said silicon film which is exposed at said trench;
(d) filling said trench with an insulating material; and
(e) performing annealing at a temperature of 600° C. or lower for one hour or more.

16. The method of manufacturing a semiconductor device according to claim 15, further comprising the step of
forming a well region in said silicon film after said step (e).

17. The method of manufacturing a semiconductor device according to claim 15, further comprising the step of
making said insulating material which is exposed at a surface have a curved shape on a side of said silicon film after said step (d).
